(19) United States
(12) Patent Application Publication
(10) Pub. No.: US 2014/0360584 A1
(43) Pub. Date: Dec. 11, 2014

(54) MANUFACTURING METHOD OF SOLAR CELL

(71) Applicant: NATIONAL DONG HWA UNIVERSITY, Hualien (TW)

(72) Inventors: CHU-HSUAN LIN, HUALIEN (TW); WEN-TZU HSU, PENGHU COUNTY (TW); ZONG-SIAN TSAI, NEW TAIPEI CITY (TW); CHUN-TIEN YU, TAIPEI CITY (TW)

(21) Appl. No.: 13/912,485

(22) Filed: Jun. 7, 2013

(51) Int. Cl. H01L 31/18; H01L 31/0216

(52) U.S. Cl. CPC H01L 31/18; H01L 31/02167
USPC 136/261; 136/252; 438/98

(57) ABSTRACT

A manufacturing method of a solar cell includes the following steps, providing a substrate, which includes a first conductivity type semi-conductor layer and a second conductivity type semi-conductor layer. The conductivity type of the first conductivity type semi-conductor layer is opposite to the conductivity type of the second conductivity type semi-conductor layer. A graphene oxide layer is formed on the substrate and the graphene oxide layer contacts with the second conductivity type semi-conductor layer. A first electrode and a second electrode are formed on the substrate. The first electrode contacts with the first conductivity type semi-conductor layer, and the second electrode contacts with the second conductivity type semi-conductor layer.

### BACKGROUND

1. Technical Field

The present disclosure relates to a solar cell; in particular, a manufacturing method of a solar cell.

2. Description of Related Art

Currently, the common solar cell is usually formed by semiconductor materials, for example silicon materials. When the sunlight transmits into the solar cell, the semiconductor materials would absorb the light energy and generate electron-hole pairs. The electron-hole pairs can be separated by the built-in electric field so that the solar cell provides electric power.

In general, there are many defects exist in the surface of the silicon materials, for example dangling bonds. Those dangling bonds can trap the electron-hole pairs of the solar cell to decrease photoelectric conversion efficiency of the solar cell. Thus, someone looks for the methods of forming passivation layer to decrease the dangling bonds trapping the electron-hole pairs so that the recombination rate.

### SUMMARY

An embodiment of the present disclosure provides a manufacturing method of a solar cell which is used to decrease the cost of forming a passivation layer and an anti-reflection layer of the solar cell.

An embodiment of the present disclosure provides a manufacturing method of a solar cell. The manufacturing method of the solar cell includes the following steps, providing a substrate, which includes a first conductivity type semi-conductor layer and a second conductivity type semi-conductor layer. The conductivity type of the first conductivity type semi-conductor layer is opposite to the conductivity type of the second conductivity type semi-conductor layer. A graphene oxide layer is formed on the substrate and the graphene oxide layer contacts with the second conductivity type semi-conductor layer. A first electrode and a second electrode are formed on the substrate. The first electrode contacts with the first conductivity type semi-conductor layer, and the second electrode contacts with the second conductivity type semi-conductor layer.

To sum up, the present disclosure provides a manufacturing method of a solar cell. The graphene oxide layer is formed on the substrate and the graphene oxide layer touches the second conductivity type semi-conductor layer. The graphene oxide layer is not only to be a passivation layer of the solar cell to decrease the recombination rate of electrons and holes but also to be anti-reflection layer to decrease the incident light reflectance of the solar cell so that the absorbed incident light of the solar cell increase. Thus, the photoelectric conversion efficiency of the solar cell enhances. Besides, the graphene oxide layer is formed by steeping the substrate in a graphene oxide suspended solution. Thus, the producing process of the graphene oxide layer is simpler so that the cost of forming a passivation layer and an anti-reflection layer of the solar cell can be decreased.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to facilitate further understanding of the present disclosure, and are incorporated in and constitute a part of this specification. The drawings illustrate exemplary embodiments of the present disclosure and, together with the description, serve to explain the principles of the present disclosure.

FIG. 1 depicts a structure schematic diagram of a solar cell in accordance with an embodiment of the present disclosure.

FIG. 2 is a flowchart diagram depicting manufacturing method of a solar cell in accordance with an embodiment of the present disclosure.

FIG. 3 illustrates the reflectance of a solar cell as a function of wavelength in accordance with an embodiment of the present disclosure.

FIG. 4 illustrates the voltage as a function of capacitance for a metal oxide semiconductor disposed the graphene oxide layer.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or similar parts.

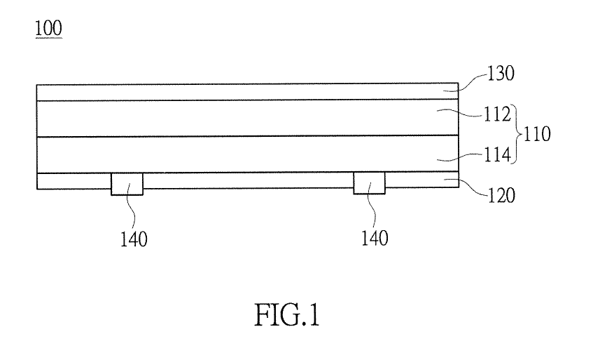

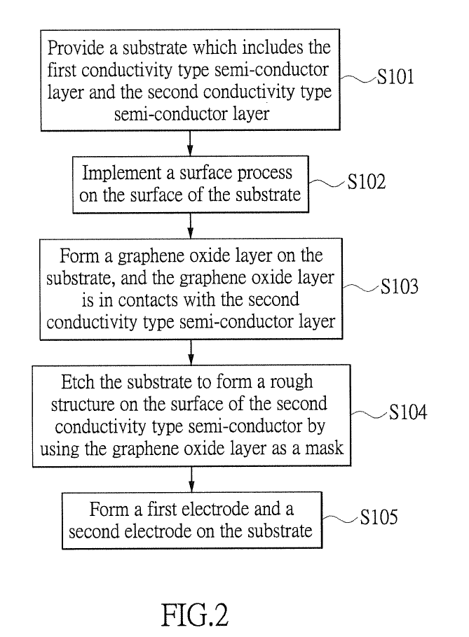

FIG. 1 illustrates a structure schematic diagram of a solar cell in accordance with an embodiment of the present disclosure. FIG. 2 is a flowchart diagram depicting manufacturing method of a solar cell in accordance with an embodiment of the present disclosure. Please refer to FIGS. 1 and 2.

The solar cell 100 includes a substrate 110, a grapheme oxide layer 120, a first electrode 130 and a second electrode 140. The grapheme oxide layer 120 is disposed above the substrate 100, and the first electrode 130 and the second electrode 140 contact with the substrate 110 distinctively. It is worth mentioning that the manufacturing method of a solar cell is mainly forming the graphene oxide layer 120 on the substrate 110, and forming the first electrode 130 and the second electrode 140 on the substrate 110. Hence, the solar cell 100 is approximately formed.

First, in the step S101, the substrate 110 is provided. The substrate 110 includes the first conductivity type semi-conductor layer 112 and the second conductivity type semi-conductor layer 114. The conductivity type of the first conductivity type semi-conductor layer 112 is opposite to the conductivity type of the second conductivity type semi-conductor layer. It is worth mentioning that the first conductivity type semi-conductor 112 is mainly n-type semiconductor layer doped with group V element, and the second conductivity type semi-conductor 114 is mainly p-type semiconductor layer doped with group III element.

Generally speaking, the substrate 110 is a silicon substrate, which may be made of single crystal silicon, polycrystal silicon, or amorphous silicon. Alternatively, the substrate 110 may include other non-silicon sunlight absorbing material. In the present embodiment, the substrate 110 is single crystal silicon, and the first conductivity type semi-conductor 112 is contact with the second conductivity type semi-conductor 114 so as to form a p-n junction at an interface between the first conductivity type semi-conductor 112 and the second conductivity type semi-conductor 114. However, in other embodiment, the substrate 110 can be an amorphous silicon, which further includes a intrinsic semiconductor layer or a low-doped semiconductor (not shown). The first conductivity type semi-conductor 112 and the second conductivity type semi-conductor 114 are located at two side of the intrinsic semiconductor layer distinctively. Thus, the solar cell 100 can convert the absorbed light into electrical energy through photovoltaic effect. However, the present disclosure is not limited to the material of the substrate 110.

Besides, in order to increase the surface polarity of the substrate 110, the surface of the substrate 110 can be implemented a surface process. Specificity, in the step S102, the substrate 110 is steeped in a SC1 (Standard Cleaning 1) solution. The SC1 solution includes NH₄OH, H₂O₂, and deionized water, in which the proportion of NH₄OH, H₂O₂ and deionized water is between 1:1:6 to 1:2:8. It is worth mentioning that the SC1 solution has OH functional group, and OH functional group can form polar covalent bonds. Thus, the surface of the substrate 110 which steeped in the SC1 solution has polarity. Although the substrate 110 in the present embodiment is implemented a surface process, but the present does not limited to surface process.

In the step S103, a graphene oxide layer 120 is formed on the substrate 110 and the graphene oxide layer 120 is in contacts with the second conductivity type semi-conductor layer 114. In the present embodiment, the substrate 110 is steeped in a graphene oxide suspended solution so as to form graphene oxide layer 120. Concretely speaking, a graphite is oxidized to form a graphite oxide by putting the graphite into H₂SO₄ and KMnO₄ to get graphite oxide and using H₂O₂ to oxidized. Then, the graphite oxide is putted into deionized water to form a graphite oxide solution. Then, the graphite oxide solution is implemented via a first ultrasonic agitation process and a first centrifugation process through an ultrasonic agitation device and a centrifugal device to form the graphene oxide suspended solution. A time period of the first ultrasonic agitation process is between 20 to 60 minutes, a rotational speed of the first centrifugal processing is between 500 to 15,000 rpm (revolutions per minute, rpm), a time period of the first centrifugal processing is between 20 to 60 minutes. Thus, the graphene oxide suspended solution is formed from the graphite oxide solution.

It is worth mentioning that the size of the graphene oxide chips hangs on the time period or number of times of ultrasonic agitation process and centrifugation process, so that the size of the graphene oxide chips can be changed by adjusting the time period or number of times of ultrasonic agitation process and centrifugation process. Thus, in order to decrease the size of the graphene oxide chips, the above-mentioned graphene oxide suspended solution is implemented a second ultrasonic agitation process and a second centrifugation process. A time period of the second ultrasonic agitation process is between 60 to 150 minutes, a rotational speed of the second centrifugal processing is between 500 to 15,000 rpm, a time period of the second centrifugal processing is between 20 to 60 minutes. However, the present disclosure does not limited to the condition of ultrasonic agitation process and centrifugation process.

Next, part of the graphene oxide suspended solution is drawn through a dropper. Then, the graphene oxide suspended solution is dropped into the surface of the substrate 110, or the substrate 110 is steeped in a graphene oxide suspended solution. Thus, the second conductivity type semi-conductor layer 114 can touch the graphene oxide suspended solution. The substrate 110 steeped the graphene oxide suspended solution is dried. The drying ways can be nature air drying or heating drying, the present does not limited to the drying ways. Therefore, the graphene oxide chips can deposit on the substrate 110 to form the graphene oxide layer 120, and the graphene oxide layer 120 can touch the second conductivity type semi-conductor layer 114.

However, in other embodiment, the graphene oxide layer 120 can be formed through chemical vapor deposition, mechanical exfoliation, or epitaxial growth. Or, the graphene oxide layer 120 can also be formed by oxidizing the bonds of graphene after forming graphene or graphite layers.

In addition, it is worth mentioning that the graphene oxide has polarity bonds. Thus, while the graphene oxide chips deposit on the surface of the second conductivity type semi-conductor layer 114 with the surface process, the graphene oxide chips can be more well-distributed.

In the step S105, a first electrode 130 and a second electrode 140 are formed on the substrate 110. As shown in FIG. 2, the first electrode 130 is disposed on and touches the first conductivity type semi-conductor layer 112. The second electrode 140 penetrates through part of the graphene oxide layer 120 and touches the second conductivity type semi-conductor layer 114.

Specificity, the first electrode 130 and the second electrode 140 can be conductive materials, like silver or aluminum, and forming on the substrate 110 distinctively by depositing or coating. For example, the second electrode 140 may be a silver paste and coating on the graphene oxide layer 120. The second electrode 140 can penetrate through the gaps between the graphene oxide chips then touch the second conductivity type semi-conductor layer 114 by implementing heat treatment. In addition, the graphene oxide layer 120 may be a pattern layer with many holes, and a portion of the second conductivity type semi-conductor layer 114 may be exposed through the holes. Hence, the second electrode 140 is formed on the graphene oxide layer 120 and touches the second conductivity type semi-conductor layer 114. Besides, the forming sequence of the first electrode 130 and the second electrode 140 can be simultaneous or in reverse. However, the present does not limited to the methods and forming sequence of the first electrode 130 and the second electrode 140.

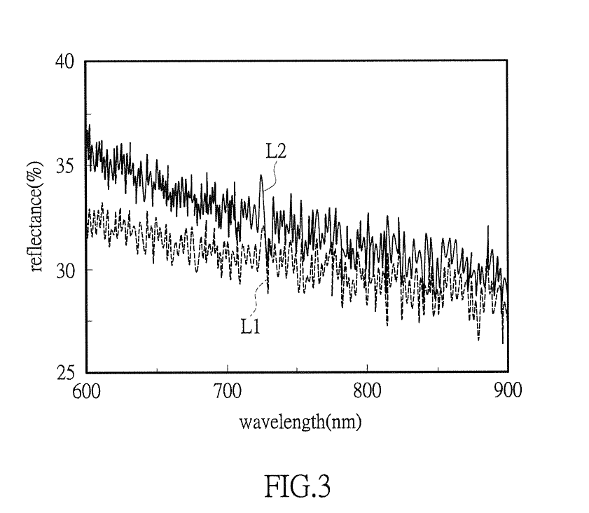

FIG. 3 illustrates the reflectance of a solar cell as a function of wavelength in accordance with an embodiment of the present disclosure. Please refer to FIG. 3. A curve L1 represents the reflectance as a function of wavelength for the solar cell 100 having the graphene oxide layer 120. A curve L2 represents the reflectance as a function of wavelength for the solar cell without the graphene oxide layer 120. As shown in FIG. 3, the reflectance of the curve L1 decreases as increasing wavelength, The reflectance of the curve L1 is smaller than the reflectance of the curve L2. Hence, the anti-reflection effect of the solar cell 100 having the graphene oxide layer 120 is good than the anti-reflection effect of the solar cell without the graphene oxide layer 120. Therefore, the graphene oxide layer 120 can be used to be an anti-reflection layer to decrease the incident light reflectance of the solar cell 100 so as to increase the incident light absorption in the solar cell 100.

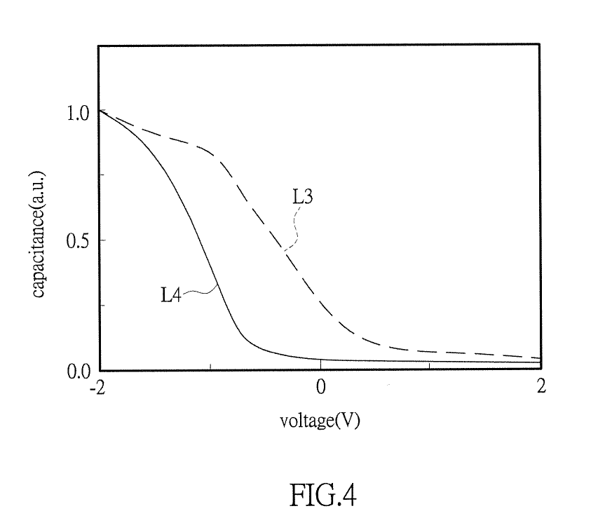

FIG. 4 illustrates the voltage as a function of capacitance for a metal oxide semiconductor disposed the graphene oxide layer. Please refer to FIG. 4. A curve L3 represents the voltage as a function of capacitance for a metal oxide semiconductor which has Al-graphene oxide-native oxide layer-Si—Al, which is formed the graphene oxide layer 120 on native oxide layer-Si and formed Al electrodes. A curve L4 represents the voltage as a function of capacitance for a metal oxide semiconductor which has Al-native oxide layer-Si—Al, which formed Al electrodes. As shown in FIG. 4, the flat band voltage value of the curve L3 representing the metal oxide semiconductor with the graphene oxide layer is larger than the flat band voltage value of the curve L4 represent for the metal oxide semiconductor without the graphene oxide layer. Namely, compared with the curve L4, the curve L3 shifts right. Hence, it means that the graphene oxide layer 120 has negative charge to passivate the surface of the substrate 110. Namely, the graphene oxide layer 120 can be the passivation layer of the solar cell 100 so that the graphene oxide layer 120 can decrease the recombination rate of electrons and holes.

Furthermore, the manufacturing method of a solar cell 100 can further include the step S104. Please refer to FIG. 2 again. In the step S104, the substrate 110 is etched to form a rough structure on the surface of the second conductivity type semi-conductor 114 by using the graphene oxide layer 120 as a mask. In general, the substrate 110 can be etched to form the rough structure so that the ratio of the reflected light decrease. Thus, the loss of incident light can be decrease. In the present embodiment, the substrate 110 is etched by using the graphene oxide layer 120 as a mask and KOH as a etching solution. The surface of the etched substrate 110 is undulating and forms the rough structure. While the incident light transmits into the end of the graphene oxide layer 120, the graphene oxide layer 120 can be used to decrease the reflectance. Although the manufacturing method of a solar cell 100 can etch the substrate 110 through the graphene oxide layer 120, the present does not limited to this.

In summary, the present disclosure provides a manufacturing method of a solar cell. The graphene oxide layer is formed on the substrate and the graphene oxide layer touches the second conductivity type semi-conductor layer. The graphene oxide layer is not only to be a passivation layer of the solar cell to decrease the recombination rate of electrons and holes but also to be anti-reflection layer to decrease the incident light reflectance of the solar cell so that the absorbed incident light of the solar cell increase. Thus, the photoelectric conversion efficiency of the solar cell enhances. Besides, the graphene oxide layer is formed by steeping the substrate in a graphene oxide suspended solution. Thus, the producing process of the graphene oxide layer is simpler so that the cost of forming a passivation layer and an anti-reflection layer of the solar cell can be decreased.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A manufacturing method of a solar cell comprising:
providing a substrate, the substrate includes a first conductivity type semi-conductor layer and a second conductivity type semi-conductor layer, wherein the conductivity type of the first conductivity type semi-conductor layer is opposite to the conductivity type of the second conductivity type semi-conductor layer;
forming a graphene oxide layer on the substrate and the graphene oxide layer contacts with the second conductivity type semi-conductor layer; and
forming a first electrode and a second electrode on the substrate, and first electrode contacts with the first conductivity type semi-conductor layer, and the second electrode contacts with the second conductivity type semi-conductor layer.

2. The manufacturing method of a solar cell according to claim 1, wherein the graphene oxide layer is formed by steeping the substrate in a graphene oxide suspended solution.

3. The manufacturing method of a solar cell according to claim 2, wherein the manufacturing method of the graphene oxide suspended solution comprising:
turning a graphite into a graphite oxide;
forming a graphite oxide solution by putting the graphene oxide into a deionized water; and
implementing a first ultrasonic agitation process and a first centrifugation process through an ultrasonic agitation device and a centrifugal device to form the graphene oxide suspended solution.

4. The manufacturing method of a solar cell according to claim 3, wherein a time period of the first ultrasonic agitation process is between 20 to 60 minutes, a rotational speed of the first centrifugal processing is between 500 to 15,000 rpm (revolutions per minute, rpm), a time period of the first centrifugal processing is between 20 to 60 minutes.

5. The manufacturing method of a solar cell according to claim 4, wherein the graphene oxide suspended solution is further implemented a second ultrasonic agitation process, a time period of the second ultrasonic agitation process is between 60 to 150 minutes, then the graphene oxide suspended solution is implemented a second centrifugation process, the rotational speed of the second centrifugal processing is between 500 to 15,000 rpm, a time period of the second centrifugal processing is between 20 to 60 minutes.

6. The manufacturing method of a solar cell according to claim 1, wherein before the graphene oxide layer is formed on the substrate, the substrate is implemented a surface process.

7. The manufacturing method of a solar cell according to claim 6, wherein the surface process comprises steeping the substrate in a SC1 solution.

8. The manufacturing method of a solar cell according to claim 1, wherein the substrate is etched to form a rough structure by using the graphene oxide layer as a mask.

9. The manufacturing method of a solar cell according to claim 1, wherein the graphene oxide layer is formed through chemical vapor deposition, mechanical exfoliation, or epitaxial growth.

10. A solar cell comprising:
a substrate, the substrate includes a first conductivity type semi-conductor layer and a second conductivity type semi-conductor layer;
a graphene oxide layer on the substrate and the graphene oxide layer contacts with the second conductivity type semi-conductor layer;
a first electrode disposed on the substrate; and
a second electrode disposed on the substrate, and first electrode contacts with the first conductivity type semi-conductor layer, and the second electrode contacts with the second conductivity type semi-conductor layer.

11. The solar cell according to claim 10, wherein the conductivity type of the first conductivity type semi-conductor layer is opposite to the conductivity type of the second conductivity type semi-conductor layer.

12. The solar cell according to claim 10, wherein the first conductivity type semi-conductor is mainly n-type semiconductor layer doped with group V element, and the second conductivity type semi-conductor is mainly p-type semiconductor layer doped with group III element.

13. The solar cell according to claim 10, wherein the substrate is a silicon substrate.
